(19) United States
(12) Patent Application Publication
(10) Pub. No.: US 2026/0073482 A1
(43) Pub. Date: Mar. 12, 2026

(54) PRODUCING AN IMAGE TO DESIGN A PRODUCT

(71) Applicant: Toyota Research Institute, Inc., Los Altos, CA (US)

(72) Inventors: Yin-Ying Chen, San Jose, CA (US); Nikos Arechiga Gonzalez, San Mateo, CA (US); Chenyang Yuan, Cambridge, MA (US); Matthew K. Hong, Mountain View, CA (US); Matthew Evans Klenk, San Francisco, CA (US)

(73) Assignees: Toyota Research Institute, Inc., Los Altos, CA (US); Toyota Jidosha Kabushiki Kaisha, Toyota-shi Aichi-ken (JP)

(21) Appl. No.: 19/060,008

(22) Filed: Feb. 21, 2025

Related U.S. Application Data
(60) Provisional application No. 63/692,242, filed on Sep. 9, 2024.

(51) Int. Cl. G06T 5/60; G06F 30/27; G06T 5/50; G06T 5/70

(52) U.S. Cl. CPC G06T 5/60; G06F 30/27; G06T 5/50; G06T 5/70; G06T 2207/20081; G06T 2207/20084; G06T 2207/20212; G06T 2207/30108

(57) ABSTRACT

A system for producing an image to design a product can include a processor and a memory. The memory can store a regularizing module, a blending module, a denoising module, and a communications module. The regularizing module can produce a regularized image of a denoised image of an interpolation of a first diffused image and a second diffused image. The regularized image can be regularized with respect to a visual pattern. The blending module can: (1) determine a blending weight and (2) produce, based on the blending weight, a blended image of the denoised image and the regularized image. The denoising module can denoise the blended image to produce the image to design the product. The communications module can cause the image to be sent to a computer-aided design system to design the product.

### CROSS-RELATED TO RELATED APPLICATIONS

The application claims the benefit of U.S. Provisional Application No. 63/692,242, filed Sep. 9, 2024, which is incorporated herein in its entirety by reference.

### TECHNICAL FIELD

The disclosed technologies are directed to producing an image to design a product.

### BACKGROUND

A design of a product can include information about one or more of a form of the product, a feature of the product, or the like. The design can take into account, for example, one or more of an aesthetic aspect of the product, a functional concern of the product, or the like. The design of the product can include, for example, an image of the product. A tool used for one or more processes to produce the design of the product can include, for example, a computer-aided design (CAD) system. Such one or more processes can include, for example, a creation of the design, a modification of the design, an analysis of the design, an optimization of the design, or the like. An output of the CAD system can be an electronic file that includes, for example, information about one or more of materials used to manufacture the product, measurements associated with the product, tolerances of the measurements, procedures associated with manufacturing the product, or the like. Additionally, for example, the information can be used to machine the product, manufacture the product, print the image of the product, or the like. For example, the output of the CAD system can be used to control a machine that manufactures the product.

### SUMMARY

In an embodiment, a system for producing an image to design a product can include a processor and a memory. The memory can store a regularizing module, a blending module, a denoising module, and a communications module. The regularizing module can include instructions that, when executed by the processor, cause the processor to produce a regularized image of a denoised image of an interpolation of a first diffused image and a second diffused image. The regularized image can be regularized with respect to a visual pattern. The blending module can include instructions that, when executed by the processor, cause the processor to: (1) determine a blending weight and (2) produce, based on the blending weight, a blended image of the denoised image and the regularized image. The denoising module can include instructions that, when executed by the processor, cause the processor to denoise the blended image to produce the image to design the product. The communications module can include instructions that, when executed by the processor, cause the processor to cause the image to be sent to a computer-aided design system to design the product.

In another embodiment, a method for producing an image to design a product can include producing, by a processor, a regularized image of a denoised image of an interpolation of a first diffused image and a second diffused image. The regularized image can be regularized with respect to a visual pattern. The method can include determining, by the processor, a blending weight. The method can include producing, by the processor and based on the blending weight, a blended image of the denoised image and the regularized image. The method can include denoising, by the processor, the blended image to produce the image to design the product. The method can include causing, by the processor, the image to be sent to a computer-aided design system to design the product.

In another embodiment, a non-transitory computer-readable medium for producing an image to design a product can include instructions that, when executed by one or more processors, cause the one or more processors to produce a regularized image of a denoised image of an interpolation of a first diffused image and a second diffused image. The regularized image can be regularized with respect to a visual pattern. The non-transitory computer-readable medium can include instructions that, when executed by one or more processors, cause the one or more processors to determine a blending weight. The non-transitory computer-readable medium can include instructions that, when executed by one or more processors, cause the one or more processors to produce, based on the blending weight, a blended image of the denoised image and the regularized image. The non-transitory computer-readable medium can include instructions that, when executed by one or more processors, cause the one or more processors to denoise the blended image to produce the image to design the product. The non-transitory computer-readable medium can include instructions that, when executed by one or more processors, cause the one or more processors to cause the image to be sent to a computer-aided design system to design the product.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 includes a block diagram of a first example of a process for producing an image to design a product, according to the disclosed technologies.

FIG. 2 includes a block diagram of a second example of the process for producing the image to design the product, according to the disclosed technologies.

FIG. 3 includes a block diagram that illustrates an example of a system for producing the image to design the product, according to the disclosed technologies.

FIG. 4 includes a diagram of an example of a first original image, according to the disclosed technologies.

FIG. 5 includes a diagram of an example of a second original image, according to the disclosed technologies.

FIG. 6 includes a diagram of an example of a denoised (or decoded denoised) image, according to the disclosed technologies.

FIG. 7 includes a diagram of a first example of a regularized image, according to the disclosed technologies.

FIG. 8 includes a diagram of a second example of the regularized image, according to the disclosed technologies.

FIG. 9 includes a diagram of an example of the image to design the product, according to the disclosed technologies.

FIGS. 10A and 10B include a flow diagram that illustrates an example of a method that is associated with producing an image to design a product, according to the disclosed technologies.

### DETAILED DESCRIPTION

The disclosed technologies are directed to producing an image to design a product. A design of the product can include, for example, an image of the product. Sometimes, for example, it can be desirable for the image of the product to be designed to combine features from one or more other images. Artificial intelligence technology can be used, for example, to produce an image that combines features from one or more other images. Such artificial intelligence technology can include, for example, a generative adversarial network (GAN), a diffusion model, or the like. For example, a diffusion model can be caused, during a training phase, to reproduce a sample by denoising an original sample to which noise has been added and can be caused thereafter, during an inference phase, to generate a novel sample from random noise. For example, the training phase, the inference phase, or both can be performed in iterations. For example, a diffusion model can be a latent diffusion model. For example, a diffusion model can be implemented using a U-net neural network, a transformer neural network, or the like. For example, the diffusion model can be a commercially available diffusion model.

For example, a first original image and a second original image can be obtained. For example: (1) a first diffused image can be produced from the first original image and (2) a second diffused image can be produced from the second original image. For example: (1) the first diffused image can be produced by adding a shared noise to the first original image and (2) the second diffused image can be produced by adding the shared noise to the second original image. For example, an interpolation of the first diffused image and the second diffused image can be produced. For example, the interpolation can be denoised to produce a denoised image. For example, the denoised image can be regularized to produce a regularized image. For example, the regularized image can be regularized with respect to a visual pattern. For example, the visual pattern can be representative of a functional constraint. By having the regularized image regularized with respect to a functional constraint, for example, the image to design the product produced by the disclosed technologies can account for one or more functional concerns of the product in addition to one or more aesthetic aspects of the product. For example, the functional constraint can include a constraint with respect to one or more of a rotational symmetry, a reflectional symmetry, a point symmetry, a structural strength, a shearing force, a resonant frequency, an aerodynamic parameter, or the like.

However, because the disclosed technologies may be implemented using a commercially available diffusion model in which the inference phase is performed in iterations, production of the regularized image may have features sufficiently different from features of a denoised image associated with training the commercially available diffusion model. In this situation, the commercially available diffusion model may require more iterations to produce the image to design the product. Therefore, the disclosed technologies can, for example: (1) determine a blending weight and (2) produce, based on the blending weight, a blended image of the denoised image and the regularized image. In this manner, features of the blended image can be more similar, than features of the regularized image, to features of a denoised image associated with training the commercially available diffusion model. In this manner, the commercially available diffusion model may produce the image to design the product from the blended image in fewer iterations than the commercially available diffusion model would produce the image to design the product from the regularized image. For example, the blended image can be denoised to produce the image to design the product. As described above, for example, producing the regularized image, determining the blending weight, producing the blended image, and denoising the blended image can be performed in iterations until the image to design the product has been produced. For example, the image to design the product can be caused to be sent to a computer-aided design (CAD) system. For example, an output of the CAD system can be used to control a machine that manufactures the product.

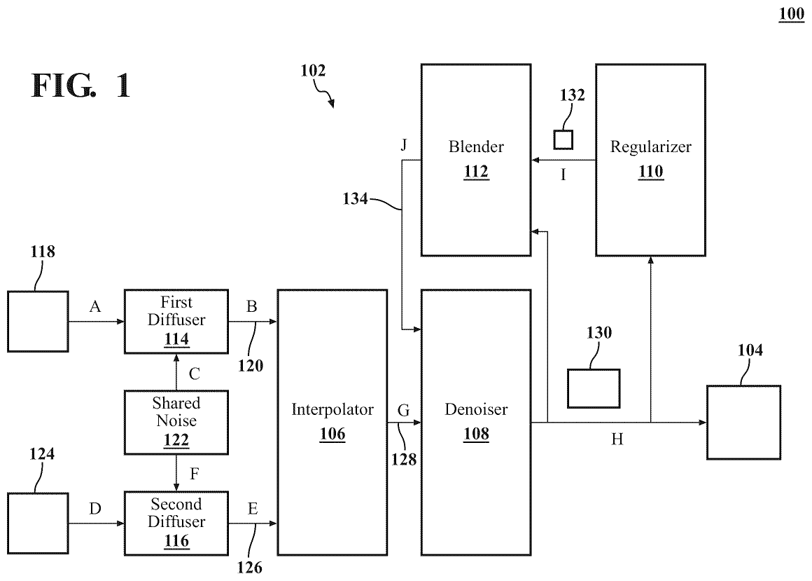

FIG. 1 includes a block diagram of a first example 100 of a process 102 for producing an image 104 to design a product, according to the disclosed technologies. The first example 100 can include an interpolator 106, a denoiser 108, a regularizer 110, and a blender 112. Additionally, the first example 100 can include a first diffuser 114 and a second diffuser 116. For example, the first diffuser 114 can receive a first original image 118 (A) and produce a first diffused image 120 (B). For example, the first diffuser 114 can produce the first diffused image 120 (B) by adding a shared noise 122 (C) to the first original image 118 (A). For example, the second diffuser 116 can receive a second original image 124 (D) and produce a second diffused image 126 (E). For example, the second diffuser 116 can produce the second diffused image 126 (E) by adding the shared noise 122 (F) to the second original image 124 (D). For example, the interpolator 106 can receive the first diffused image 120 (B) and the second diffused image 126 (E) and produce an interpolation 128 (G). For example, the denoiser 108 can receive the interpolation 128 (G) and produce a denoised image 130 (H). For example, the regularizer 110 can receive the denoised image 130 (H) and produce a regularized image 132 (I). For example, the blender 112 can receive the denoised image 130 (H) and the regularized image 132 (I) and produce a blended image 134 (J). For example, the denoiser 108 can receive the blended image 134 (J) and produce, in iterations of producing the denoised image 130 (H), the regularized image 132 (I), and the blended image 134 (J), the image 104 to design the product.

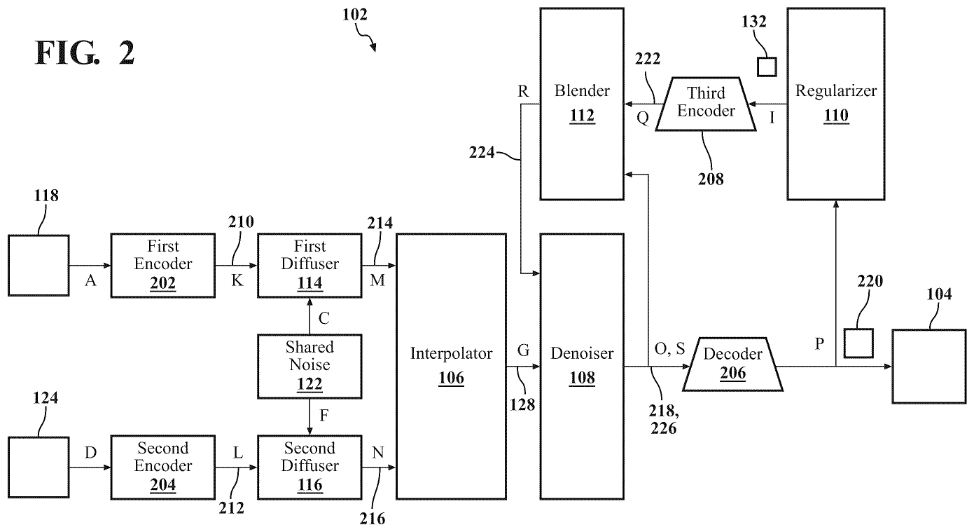

FIG. 2 includes a block diagram of a second example 200 of the process 102 for producing the image 104 to design the product, according to the disclosed technologies. The second example 200 can include the interpolator 106, the denoiser 108, the regularizer 110, the blender 112, the first diffuser 114, the second diffuser 116, the shared noise 122, a first encoder 202, a second encoder 204, a decoder 206, and a third encoder 208.

For example, the first encoder 202 can receive the first original image 118 (A) and produce a first vector 210 (K). For example, the first vector 210 can represent features of the first original image 118 as values of dimensions of the first vector 210. For example, the first vector 210 can be a first latent vector. For example, the first encoder 202 can include a machine learning model configured to identify latent features of the first original image 118. For example, such latent features can be inferred from other explicit features of the first original image 118. For example, a count of a number of the latent features used to represent the first original image 118 can be less than a count of a number of the other explicit features of the first original image 118. In this manner, having the first vector 210 be a first latent vector can reduce a count of a number of the dimensions of the first vector 210 that would otherwise be needed to represent the first original image 118.

For example, the second encoder 204 can receive the second original image 124 (D) and produce a second vector 212 (L). For example, the second vector 212 can represent features of the second original image 124 as values of dimensions of the second vector 212. For example, the second vector 212 can be a second latent vector. For example, the second encoder 204 can include a machine learning model configured to identify latent features of the second original image 124. For example, such latent features can be inferred from other explicit features of the second original image 124. For example, a count of a number of the latent features used to represent the second original image 124 can be less than a count of a number of the other explicit features of the second original image 124. In this manner, having the second vector 212 be a second latent vector can reduce a count of a number of the dimensions of the second vector 212 that would otherwise be needed to represent the second original image 124.

For example, the first diffuser 114 can receive the first vector 210 (K) and produce a first diffused vector 214 (M). For example, the first diffuser 114 can produce the first diffused vector 214 (M) by adding the shared noise 122 (C) to the first vector 210 (K). For example, the second diffuser 116 can receive the second vector 212 (L) and produce a second diffused vector 216 (N). For example, the second diffuser 116 can produce the second diffused vector 216 (N) by adding the shared noise 122 (F) to the second vector 212 (L). For example, the interpolator 106 can receive the first diffused vector 214 (M) and the second diffused vector 216 (N) and produce the interpolation 128 (G). For example, the denoiser 108 can receive the interpolation 128 (G) and produce a denoised vector 218 (O). For example, the decoder 206 can receive the denoised vector 218 (O) and produce a decoded denoised image 220 (P). For example, the regularizer 110 can receive the decoded denoised image 220 (P) and produce the regularized image 132 (I). For example, the third encoder 208 can receive the regularized image 132 (I) and produce a regularized vector 222 (Q). For example, the blender 112 can receive the denoised vector 218 (O) and the regularized vector 222 (Q) and produce a blended vector 224 (R). For example, the denoiser 108 can receive the blended vector 224 (R) and produce, in iterations of producing the denoised vector 218 (O), the decoded denoised image 220 (P), the regularized image 132 (I), the regularized vector 222 (Q), and the blended vector 224 (R), iterations of a modified denoised vector 226 (S). For example, the decoder 206 can receive the iterations of the modified denoised vector 226 (S) and produce the image 104 to design the product.

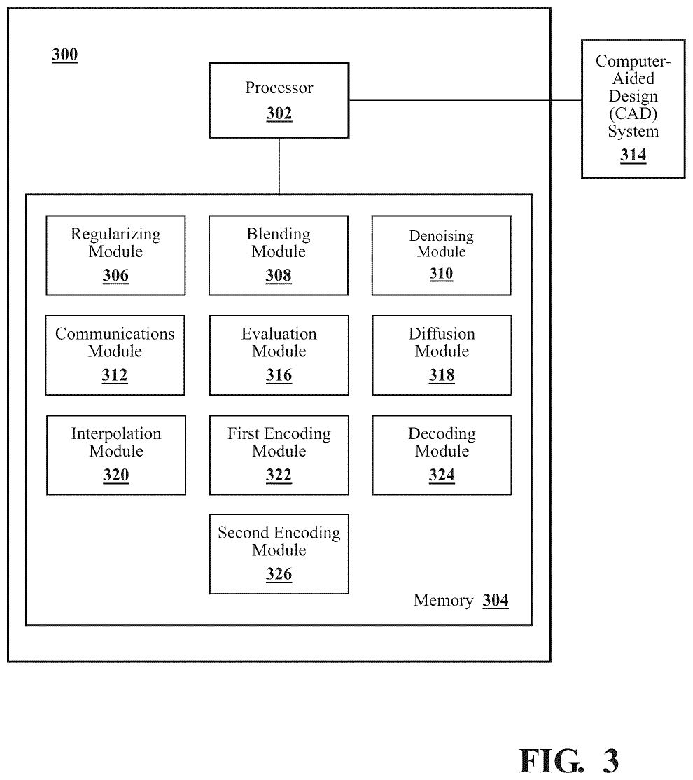

FIG. 3 includes a block diagram that illustrates an example of a system 300 for producing the image to design the product, according to the disclosed technologies. The system 300 can include, for example, a processor 302 and a memory 304. The memory 304 can be communicably coupled to the processor 302. For example, the memory 304 can store a regularizing module 306, a blending module 308, a denoising module 310, and a communications module 312. For example, the system 300 can be implemented using a U-net neural network. Alternatively, for example, the system 300 can be implemented using a transformer neural network.

For example, the regularizing module 306 can include instructions that function to control the processor 302 to produce a regularized image of a denoised image of an interpolation of a first diffused image and a second diffused image. For example, the regularized image can be regularized with respect to a visual pattern. For example, the visual pattern can be representative of a functional constraint. For example, the functional constraint can include one or more of a constraint with respect to at least one of a rotational symmetry, a reflectional symmetry, a point symmetry, a structural strength, a shearing force, a resonant frequency, an aerodynamic parameter, or the like. With reference to FIG. 1, for example, the first diffused image can be the first diffused image 120, the second diffused image can be the second diffused image 126, the interpolation can be the interpolation 128, the denoised image can be the denoised image 130, and the regularized image can be the regularized image 132.

Returning to FIG. 3, for example, the blending module 308 can include instructions that function to control the processor 302 to: (1) determine a blending weight and (2) produce, based on the blending weight, a blended image of the denoised image and the regularized image. With reference to FIG. 1, for example, the denoised image can be the denoised image 130, the regularized image can be the regularized image 132, and the blended image can be the blended image 134.

Returning to FIG. 3, for example, the denoising module 310 can include instructions that function to control the processor 302 to denoise the blended image to produce the image to design the product. With reference to FIG. 1, for example, the blended image can be the blended image 134 and the image to design the product can be the image 104 to design the product.

Returning to FIG. 3, for example, the communications module 312 can include instructions that function to control the processor 302 to cause the image to be sent to a computer-aided design (CAD) system 314 to design the product. For example, an output of the CAD system 314 can be used to control a machine that manufactures the product.

For example, the instructions to produce the regularized image, the instructions to determine the blending weight, the instructions to produce the blended image, and the instructions to denoise the blended image can be performed in iterations. For example, the instructions to denoise the blended image can include instructions to denoise, in a manner in accordance with a Denoising Diffusion Implicit Model, the blended image. For example, a final iteration, of the iterations, can be a specific count (e.g., 200) of a number of the iterations. Alternatively, for example, the memory 304 can further include an evaluation module 316. For example, the evaluation module 316 can include instructions that function to control the processor 302 to determine a value of a metric indicative of a quality of the image. For example, the metric can include one or more of a degree of conformity between the image and the visual pattern, a distance between a distribution associated with the image and a target distribution, or the like. For example, a final iteration, of the iterations, can be an iteration in which the value satisfies a threshold value.

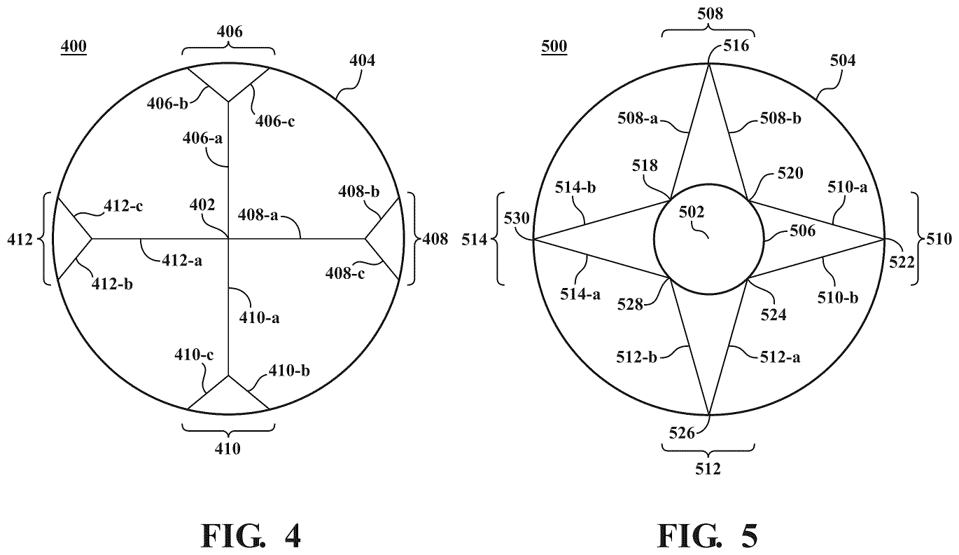

FIG. 4 includes a diagram of an example of a first original image 400, according to the disclosed technologies. For example, the first original image 400 can be of a wheel for a vehicle. For example, the first original image 400 can include a center 402 and a circle 404. For example, the first original image 400 can have a rotational symmetry. For example, the rotational symmetry can include a pattern that repeats in a specific number of positions within the first original image 400. For example, the specific number can be four; that is, the first original image 400 can be referred to as having four-fold rotational symmetry. For example, in the first original image 400, the pattern can repeat at a first position 406, a second position 408, a third position 410, and a fourth position 412. For example, the first position 406 can include a capital Y-shape in which a first linear segment 406-a is disposed in a radial direction with a first end of the first linear segment 406-a connected to the center 402 and each of a second linear segment 406-b and a third linear segment 406-c connected between a second end of the first linear segment 406-a and the circle 404 to form the capital Y-shape. For example, the second position 408 can include a capital Y-shape in which a first linear segment 408-a is disposed in a radial direction with a first end of the first linear segment 408-a connected to the center 402 and each of a second linear segment 408-b and a third linear segment 408-c connected between a second end of the first linear segment 408-a and the circle 404 to form the capital Y-shape. For example, the third position 410 can include a capital Y-shape in which a first linear segment 410-a is disposed in a radial direction with a first end of the first linear segment 410-a connected to the center 402 and each of a second linear segment 410-b and a third linear segment 410-c connected between a second end of the first linear segment 410-a and the circle 404 to form the capital Y-shape. For example, the fourth position 412 can include a capital Y-shape in which a first linear segment 412-a is disposed in a radial direction with a first end of the first linear segment 412-a connected to the center 402 and each of a second linear segment 412-b and a third linear segment 412-c connected between a second end of the first linear segment 412-a and the circle 404 to form the capital Y-shape. With reference to FIGS. 1 and 2, for example, the first original image 400 can be the first original image 118.

FIG. 5 includes a diagram of an example of a second original image 500, according to the disclosed technologies. For example, the second original image 500 can be of a wheel for a vehicle. For example, the second original image 500 can include a center 502, an outer circle 504, and a concentric inner circle 506. For example, the second original image 500 can have a rotational symmetry. For example, the rotational symmetry can include a pattern that repeats in a specific number of positions within the second original image 500. For example, the specific number can be four; that is, the second original image 500 can be referred to as having four-fold rotational symmetry. For example, in the second original image 500, the pattern can repeat at a first position 508, a second position 510, a third position 512, and a fourth position 514. For example, the first position 508 can include a triangular-shape in which: (1) a first linear segment 508-a is connected between a point 516 on the outer circle 504 and a point 518 on the concentric inner circle 506 and (2) a second linear segment 508-b is connected between the point 516 on the outer circle 504 and a point 520 on the concentric inner circle 506. For example, the second position 510 can include a triangular-shape in which: (1) a first linear segment 510-a is connected between a point 522 on the outer circle 504 and the point 520 on the concentric inner circle 506 and (2) a second linear segment 510-b is connected between the point 522 on the outer circle 504 and a point 524 on the concentric inner circle 506. For example, the third position 512 can include a triangular-shape in which: (1) a first linear segment 512-a is connected between a point 526 on the outer circle 504 and the point 524 on the concentric inner circle 506 and (2) a second linear segment 512-b is connected between the point 526 on the outer circle 504 and a point 528 on the concentric inner circle 506. For example, the fourth position 514 can include a triangular-shape in which: (1) a first linear segment 514-a is connected between a point 530 on the outer circle 504 and the point 528 on the concentric inner circle 506 and (2) a second linear segment 514-b is connected between the point 530 on the outer circle 504 and the point 518 on the concentric inner circle 506. With reference to FIGS. 1 and 2, for example, the second original image 500 can be the second original image 124.

Returning to FIG. 3, additionally, for example, the memory 304 can further include a diffusion module 318 and an interpolation module 320. For example, the diffusion module 318 can include instructions that function to control the processor 302 to: (1) produce the first diffused image and (2) produce the second diffused image. For example, the instructions to produce the first diffused image can include instructions to add a shared noise to a first original image. For example, the instructions to produce the second diffused image can include instructions to add the shared noise to a second original image. For example, the interpolation module 320 can include instructions that function to control the processor 302 to produce the interpolation. For example, the interpolation can include one or more of a spherical linear interpolation, a weighted average interpolation, or the like. For example, the denoising module 310 can further include instructions to produce the denoised image. With reference to FIG. 1, for example, the first original image can be the first original image 118, the first diffused image can be the first diffused image 120, the shared noise can be the shared noise 122, the second original image can be the second original image 124, the second diffused image can be the second diffused image 126, the interpolation can be the interpolation 128, and the denoised image can be the denoised image 130.

Returning to FIG. 3, additionally and alternatively, for example, the memory 304 can further include a first encoding module 322, a decoding module 324, and a second encoding module 326. For example, the first encoding module 322 can include instructions that function to control the processor 302 to: (1) encode the first original image into a first vector and (2) encode the second original image into a second vector. For example, the first vector can be a first latent vector. For example, the second vector can be a second latent vector. For example, the instructions to produce the first diffused image can include instructions to produce a first diffused vector by adding the shared noise to the first vector. For example, the instructions to produce the second diffused image can include instructions to produce a second diffused vector by adding the shared noise to the second vector. For example, the instructions to produce the interpolation can include instructions to produce an interpolation of the first diffused vector and the second diffused vector. For example, the instructions to produce the denoised image can include instructions to produce a denoised vector. For example, the decoding module 324 can include instructions that function to control the processor 302 to decode the denoised vector to produce a decoded denoised image. For example, the instructions to produce the regularized image of the denoised image can include instructions to produce the regularized image of the decoded denoised image. For example, the second encoding module 326 can include instructions that function to control the processor 302 to encode the regularized image into a regularized vector. For example, the instructions to produce the blended image of the denoised image and the regularized image can include instructions to produce a blended vector of the denoised vector and the regularized vector. For example, the instructions to denoise the blended image to produce the image to design the product can include instructions to denoise the blended vector to produce a modified denoised vector. For example, the decoding module 324 can further include instructions to decode the modified denoised vector to produce the image to design the product.

With reference to FIG. 2, for example, the first original image can be the first original image 118, the first vector can be the first vector 210, the second original image can be the second original image 124, the second vector can be the second vector 212, the first diffused vector can be the first diffused vector 214, the shared noise can be the shared noise can be the shared noise 122, the second diffused vector can be the second diffused vector 216, the interpolation can be the interpolation 128, the denoised vector can be the denoised vector 218, the decoded denoised image can be the decoded denoised image 220, the regularized image can be the regularized image 132, the regularized vector can be the regularized vector 222, the blended vector can be the blended vector 224, the modified denoised vector can be the modified denoised vector 226, and the image to design the product can be the image 104 to design the product.

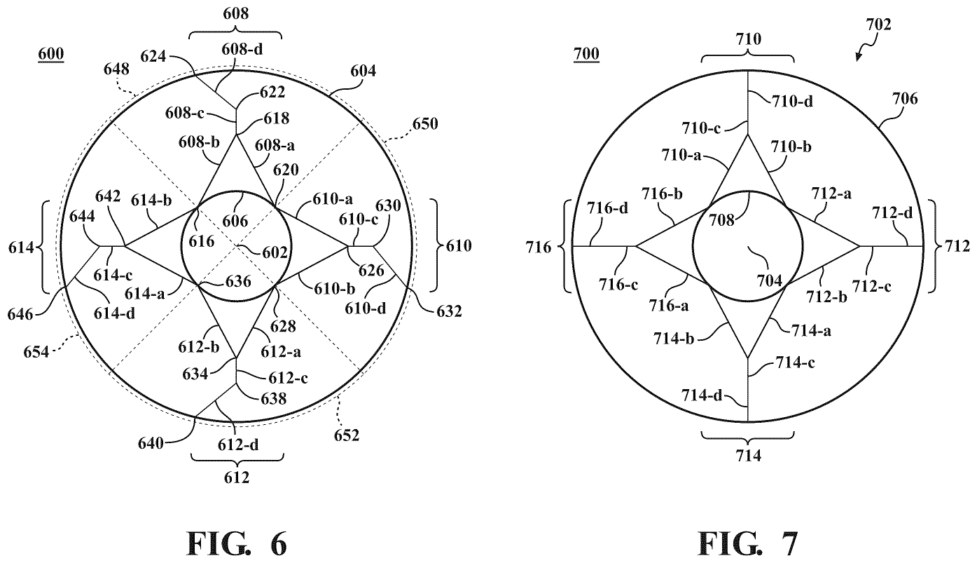

FIG. 6 includes a diagram of an example of a denoised (or decoded denoised) image 600, according to the disclosed technologies. For example, the denoised (or decoded denoised) image 600 can include a center 602, an outer circle 604, and a concentric inner circle 606. For example, the denoised (or decoded denoised) image 600 can include a first position 608, a second position 610, a third position 612, and a fourth position 614.

For example, the first position 608 can include a first linear segment 608-a, a second linear segment 608-b, a third linear segment 608-c, and a fourth linear segment 608-d. For example, the first linear segment 608-a can be connected between a point 616 on the concentric inner circle 606 and a point 618 on a first other concentric circle (not illustrated) between the outer circle 604 and the inner concentric circle 606, the second linear segment 608-b can be connected between a point 620 on the concentric inner circle 606 and the point 618, the third linear segment 608-c can be disposed in a radial direction and connected between the point 618 and a point 622 on a second other concentric circle (not illustrated) between the outer circle 604 and the first other concentric circle, and the fourth linear segment 608-d can be connected between the point 622 and a point 624 on the outer circle 604. For example, an obtuse angle can be formed in a counterclockwise direction between the third linear segment 608-c and the fourth linear segment 608-d.

For example, the second position 610 can include a first linear segment 610-a, a second linear segment 610-b, a third linear segment 610-c, and a fourth linear segment 610-d. For example, the first linear segment 610-a can be connected between the point 620 and a point 626 on the first other concentric circle (not illustrated), the second linear segment 610-b can be connected between a point 628 on the concentric inner circle 606 and the point 626, the third linear segment 610-c can be disposed in a radial direction and connected between the point 626 and a point 630 on the second other concentric circle (not illustrated), and the fourth linear segment 610-d can be connected between the point 630 and a point 632 on the outer circle 604. For example, an obtuse angle can be formed in a clockwise direction between the third linear segment 610-c and the fourth linear segment 610-d.

For example, the third position 612 can include a first linear segment 612-a, a second linear segment 612-b, a third linear segment 612-c, and a fourth linear segment 612-d. For example, the first linear segment 612-a can be connected between the point 628 and a point 634 on the first other concentric circle (not illustrated), the second linear segment 612-b can be connected between a point 636 on the concentric inner circle 606 and the point 634, the third linear segment 612-c can be disposed in a radial direction and connected between the point 634 and a point 638 on the second other concentric circle (not illustrated), and the fourth linear segment 612-d can be connected between the point 638 and a point 640 on the outer circle 604. For example, an obtuse angle can be formed in a clockwise direction between the third linear segment 612-c and the fourth linear segment 612-d.

For example, the fourth position 614 can include a first linear segment 614-a, a second linear segment 614-b, a third linear segment 614-c, and a fourth linear segment 614-d. For example, the first linear segment 614-a can be connected between the point 636 and a point 642 on the first other concentric circle (not illustrated), the second linear segment 614-b can be connected between the point 616 and the point 642, the third linear segment 614-c can be disposed in a radial direction and connected between the point 642 and a point 644 on the second other concentric circle (not illustrated), and the fourth linear segment 614-d can be connected between the point 644 and a point 646 on the outer circle 604. For example, an obtuse angle can be formed in a counterclockwise direction between the third linear segment 614-c and the fourth linear segment 614-d.

Because the obtuse angle formed between the third linear segment 608-c and the fourth linear segment 608-d and the obtuse angle formed between the third linear segment 614-c and the fourth linear segment 614-d are in counterclockwise directions, but the obtuse angle formed between the third linear segment 610-c and the fourth linear segment 610-d and the obtuse angle formed between the third linear segment 612-c and the fourth linear segment 612-d are in clockwise directions, the denoised (or decoded denoised) image 600 lacks a rotational symmetry.

Returning to FIG. 3, for example, the instructions to produce the regularized image can include instructions to produce, from the denoised (or decoded denoised) image, a set of sub-images at a set of positions within the denoised image. For example, each sub-image, of the set of sub-images, can be associated with a corresponding resemblance to a pattern and a corresponding position within the set of positions.

With reference to FIG. 6, for example, the denoised (or decoded denoised) image 600 can include a first sub-image 648 at the first position 608, a second sub-image 650 at the second position 610, a third sub-image 652 at the third position 612, and a fourth sub-image 654 at the fourth position 614. For example, an arrangement of the first linear segment 608-a, the second linear segment 608-b, and the third linear segment 608-c in the first sub-image 648 can be identical to an arrangement, respectively, of the first linear segment 610-a, the second linear segment 610-b, and the third linear segment 610-c in the second sub-image 650, which can be identical to an arrangement, respectively, of the first linear segment 612-a, the second linear segment 612-b, and the third linear segment 612-c in the third sub-image 652, which can be identical to an arrangement, respectively, of the first linear segment 614-a, the second linear segment 614-b, and the third linear segment 614-c in the fourth sub-image 654. However, because an arrangement of the fourth linear segment 608-d in first sub-image 648 and an arrangement of the fourth linear segment 614-d in fourth sub-image 654 are different from an arrangement of the fourth linear segment 610-d in second sub-image 650 and an arrangement of the fourth linear segment 612-d in third sub-image 652, each of the first sub-image 648, the second sub-image 650, the third sub-image 652, and the fourth sub-image 654 can be associated with a corresponding resemblance to a pattern rather than a corresponding pattern.

For example, the instructions to produce the regularized image can further include instructions to produce an average sub-image. For example, a value of each pixel in the average sub-image can be an average of values of corresponding pixels in sub-images in the set of sub-images. For example, the instructions to produce the regularized image can further include instructions to cause a copy of the average sub-image to be positioned at each position in the set of positions to produce the regularized image.

FIG. 7 includes a diagram of a first example 700 of a regularized image 702, according to the disclosed technologies. The first example 700 of the regularized image 702 can include a center 704, an outer circle 706, and a concentric inner circle 708. The first example 700 of the regularized image 702 can include a first position 710, a second position 712, a third position 714, and a fourth position 716.

For example, the first position 710 can include a first linear segment 710-a, a second linear segment 710-b, a third linear segment 710-c, and a fourth linear segment 710-d. For example, the first linear segment 710-a can be an average of the first linear segment 608-a, the first linear segment 610-a, the first linear segment 612-a, and the first linear segment 614-a. For example, the second linear segment 710-b can be an average of the second linear segment 608-b, the second linear segment 610-b, the second linear segment 612-b, and the second linear segment 614-b. For example, the third linear segment 710-c can be an average of the third linear segment 608-c, the third linear segment 610-c, the third linear segment 612-c, and the third linear segment 614-c. For example, the fourth linear segment 710-d can be an average of the fourth linear segment 608-d, the fourth linear segment 610-d, the fourth linear segment 612-d, and the fourth linear segment 614-d.

For example, the second position 712 can include a first linear segment 712-a, a second linear segment 712-b, a third linear segment 712-c, and a fourth linear segment 712-d. For example, the first linear segment 712-a can be an average of the first linear segment 608-a, the first linear segment 610-a, the first linear segment 612-a, and the first linear segment 614-a. For example, the second linear segment 712-b can be an average of the second linear segment 608-b, the second linear segment 610-b, the second linear segment 612-b, and the second linear segment 614-b. For example, the third linear segment 712-c can be an average of the third linear segment 608-c, the third linear segment 610-c, the third linear segment 612-c, and the third linear segment 614-c. For example, the fourth linear segment 712-d can be an average of the fourth linear segment 608-d, the fourth linear segment 610-d, the fourth linear segment 612-d, and the fourth linear segment 614-d.

For example, the third position 714 can include a first linear segment 714-a, a second linear segment 714-b, a third linear segment 714-c, and a fourth linear segment 714-d. For example, the first linear segment 714-a can be an average of the first linear segment 608-a, the first linear segment 610-a, the first linear segment 612-a, and the first linear segment 614-a. For example, the second linear segment 714-b can be an average of the second linear segment 608-b, the second linear segment 610-b, the second linear segment 612-b, and the second linear segment 614-b. For example, the third linear segment 714-c can be an average of the third linear segment 608-c, the third linear segment 610-c, the third linear segment 612-c, and the third linear segment 614-c. For example, the fourth linear segment 714-d can be an average of the fourth linear segment 608-d, the fourth linear segment 610-d, the fourth linear segment 612-d, and the fourth linear segment 614-d.

For example, the fourth position 716 can include a first linear segment 716-a, a second linear segment 716-b, a third linear segment 716-c, and a fourth linear segment 716-d. For example, the first linear segment 716-a can be an average of the first linear segment 608-a, the first linear segment 610-a, the first linear segment 612-a, and the first linear segment 614-a. For example, the second linear segment 716-b can be an average of the second linear segment 608-b, the second linear segment 610-b, the second linear segment 612-b, and the second linear segment 614-b. For example, the third linear segment 716-c can be an average of the third linear segment 608-c, the third linear segment 610-c, the third linear segment 612-c, and the third linear segment 614-c. For example, the fourth linear segment 716-d can be an average of the fourth linear segment 608-d, the fourth linear segment 610-d, the fourth linear segment 612-d, and the fourth linear segment 614-d.

Alternatively, for example, the instructions to produce the regularized image can include instructions to produce, from the denoised (or decoded denoised) image, a set of sub-images at a set of positions within the denoised image. For example, each sub-image, of the set of sub-images, can be associated with a corresponding resemblance to a pattern and a corresponding position within the set of positions. For example, the instructions to produce the regularized image can further include instructions to select, from the set of sub-images, a specific sub-image. With reference to FIG. 6, for example, the specific sub-image can be the first sub-image 646. For example, the instructions to produce the regularized image can further include instructions to cause a copy of the specific sub-image to be positioned at each position in the set of positions to produce the regularized image.

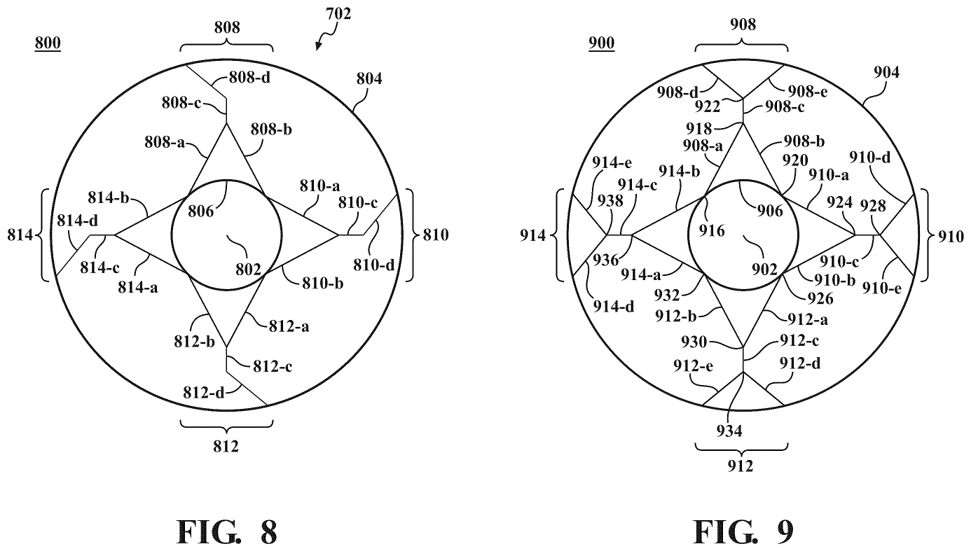

FIG. 8 includes a diagram of a second example 800 of the regularized image 702, according to the disclosed technologies. The second example 800 of the regularized image 702 can include a center 802, an outer circle 804, and a concentric inner circle 806. The second example 800 of the regularized image 702 can include a first position 808, a second position 810, a third position 812, and a fourth position 814.

For example, the first position 808 can include a first linear segment 808-a, a second linear segment 808-b, a third linear segment 808-c, and a fourth linear segment 808-d. For example, the first linear segment 808-a can be the first linear segment 608-a. For example, the second linear segment 808-b can be the second linear segment 608-b. For example, the third linear segment 808-c can be the third linear segment 608-c. For example, the fourth linear segment 808-d can be the fourth linear segment 608-d.

For example, the second position 810 can include a first linear segment 810-a, a second linear segment 810-b, a third linear segment 810-c, and a fourth linear segment 810-d. For example, the first linear segment 810-a can be the first linear segment 608-a. For example, the second linear segment 810-b can be the second linear segment 608-b. For example, the third linear segment 810-c can be the third linear segment 608-c. For example, the fourth linear segment 810-d can be the fourth linear segment 608-d.

For example, the third position 812 can include a first linear segment 812-a, a second linear segment 812-b, a third linear segment 812-c, and a fourth linear segment 812-d. For example, the first linear segment 812-a can be the first linear segment 608-a. For example, the second linear segment 812-b can be the second linear segment 608-b. For example, the third linear segment 812-c can be the third linear segment 608-c. For example, the fourth linear segment 812-d can be the fourth linear segment 608-d.

For example, the fourth position 814 can include a first linear segment 814-a, a second linear segment 814-b, a third linear segment 814-c, and a fourth linear segment 814-d. For example, the first linear segment 814-a can be the first linear segment 608-a. For example, the second linear segment 814-b can be the second linear segment 608-b. For example, the third linear segment 814-c can the third linear segment 608-c. For example, the fourth linear segment 814-d can be the fourth linear segment 608-d.

For example, the instructions to determine the blending weight can include instructions to determine an absolute value of a cosine similarity between the denoised image (or vector) and the regularized image (or vector). For example, the instructions to produce the blended image (or vector) can include: (1) instructions to determine a first product, (2) instructions to determine a difference, (3) instructions to determine a second product, and (4) instructions to determine a sum. For example, the first product can be equal to the regularized image (or vector) multiplied by the blending weight. For example, the difference can be equal to the blending weight subtracted from one. For example, the second product can be equal to the denoised image (or vector) multiplied by the difference. For example, the sum can be equal to the first product added to the second product.

Additionally, for example, the instructions to determine the blending weight can be performed in iterations and can further include instructions to determine a third product. For example, the third product can be equal to the absolute value of the cosine similarity multiplied by a quotient. For example, the quotient can be equal to a weight divided by a decay speed factor. For example, the decay speed factor can be equal to a time variable raised to a power of a constant. For example, the time variable can be indicative of a current count of a number of the iterations. In this manner, an effect of the regularized image (or vector) on the blended image (or vector) can be reduced with each iteration.

FIG. 9 includes a diagram of an example of an image 900 to design the product, according to the disclosed technologies. For example, the image 900 can include a center 902, an outer circle 904, and a concentric inner circle 906. For example, the image 900 can have a rotational symmetry. For example, the image 900 can include a first position 908, a second position 910, a third position 912, and a fourth position 914.

For example, the first position 908 can include a first linear segment 908-a, a second linear segment 908-b, a third linear segment 908-c, a fourth linear segment 908-d, and a fifth linear segment 908-e. For example, the first linear segment 908-a can be connected between a point 916 on the concentric inner circle 906 and a point 918 on a first other concentric circle (not illustrated) between the outer circle 904 and the inner concentric circle 906, the second linear segment 908-b can be connected between a point 920 on the concentric inner circle 906 and the point 918, the third linear segment 908-c can be disposed in a radial direction and connected between the point 918 and a point 922 on a second other concentric circle (not illustrated) between the outer circle 904 and the first other concentric circle, and each of the fourth linear segment 908-d and the fifth linear segment 908-e can be connected between the point 922 and the outer circle 904 to form a capital Y-shape.

For example, the second position 910 can include a first linear segment 910-a, a second linear segment 910-b, a third linear segment 910-c, a fourth linear segment 910-d, and a fifth linear segment 910-e. For example, the first linear segment 910-a can be connected between the point 920 and a point 924 on the first other concentric circle (not illustrated), the second linear segment 910-b can be connected between a point 926 on the concentric inner circle 906 and the point 924, the third linear segment 910-c can be disposed in a radial direction and connected between the point 924 and a point 928 on the second other concentric circle (not illustrated), and each of the fourth linear segment 910-d and the fifth linear segment 910-d can be connected between the point 928 and the outer circle 904 to form a capital Y-shape.

For example, the third position 912 can include a first linear segment 912-a, a second linear segment 912-b, a third linear segment 912-c, a fourth linear segment 912-d, and a fifth linear segment 912-e. For example, the first linear segment 912-a can be connected between the point 926 and a point 930 on the first other concentric circle (not illustrated), the second linear segment 912-b can be connected between a point 932 on the concentric inner circle 906 and the point 930, the third linear segment 912-c can be disposed in a radial direction and connected between the point 930 and a point 934 on the second other concentric circle (not illustrated), and each of the fourth linear segment 912-d and the fifth linear segment 912-e can be connected between the point 934 and the outer circle 904 to form a capital Y-shape.

For example, the fourth position 914 can include a first linear segment 914-a, a second linear segment 914-b, a third linear segment 914-c, a fourth linear segment 914-d, and a fifth linear segment 914-e. For example, the first linear segment 914-a can be connected between the point 932 and a point 936 on the first other concentric circle (not illustrated), the second linear segment 914-b can be connected between the point 916 and the point 936, the third linear segment 914-c can be disposed in a radial direction and connected between the point 936 and a point 938 on the second other concentric circle (not illustrated), and each of the fourth linear segment 914-d and the fifth linear segment 914-e can be connected between the point 938 and the outer circle 904 to form a capital Y-shape.

With reference to FIGS. 1 and 2, for example, the image 900 to design a product can be the image 104 to design the product.

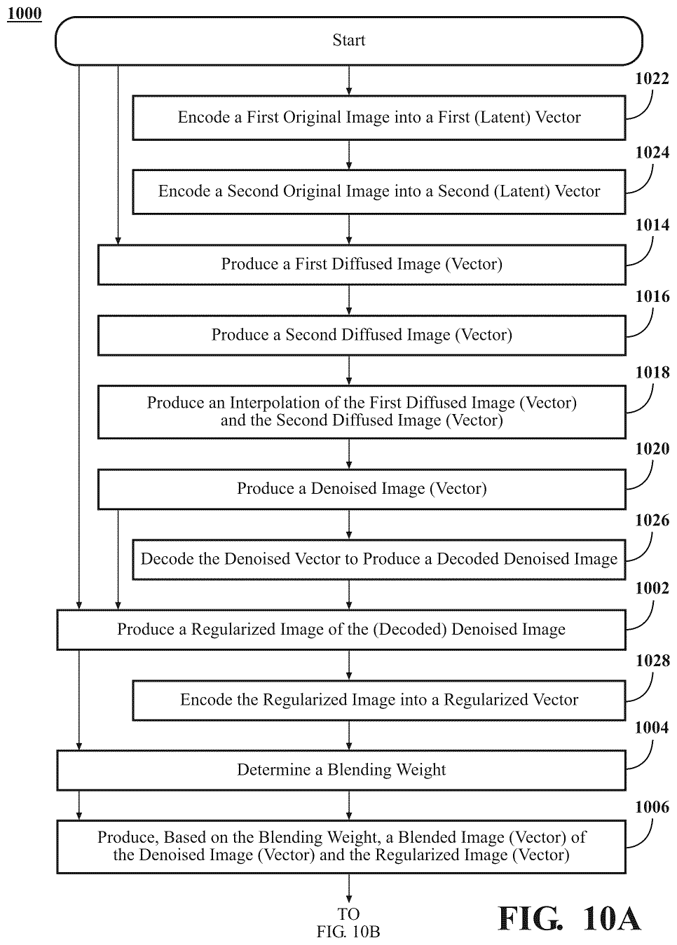

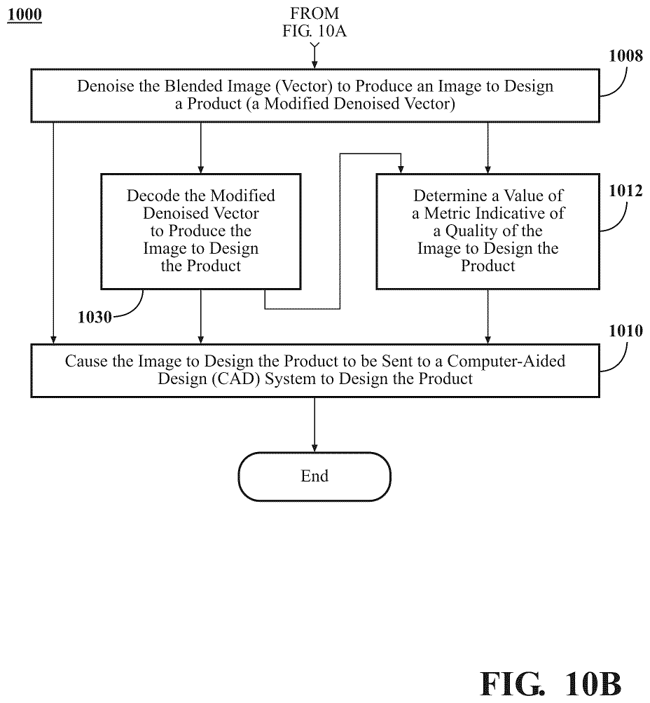

FIGS. 10A and 10B include a flow diagram that illustrates an example of a method 1000 that is associated with producing an image to design a product, according to the disclosed technologies. Although the method 1000 is described in combination with the system 300 illustrated in FIG. 3, one of skill in the art understands, in light of the description herein, that the method 1000 is not limited to being implemented by the system 300 illustrated in FIG. 3. Rather, the system 300 illustrated in FIG. 3 is an example of a system that may be used to implement the method 1000. Additionally, although the method 1000 is illustrated as a generally serial process, various aspects of the method 1000 may be able to be executed in parallel. For example, the method 1000 can be implemented using a U-net neural network. Alternatively, for example, the method 1000 can be implemented using a transformer neural network.

In FIG. 10A, in the method 1000, at an operation 1002, for example, the regularizing module 306 can produce a regularized image of a denoised image of an interpolation of a first diffused image and a second diffused image. For example, the regularized image can be regularized with respect to a visual pattern. For example, the visual pattern can be representative of a functional constraint. For example, the functional constraint can include one or more of a constraint with respect to at least one of a rotational symmetry, a reflectional symmetry, a point symmetry, a structural strength, a shearing force, a resonant frequency, an aerodynamic parameter, or the like. For example, rotational symmetry can include a pattern that repeats in a specific number of positions within an image.

At an operation 1004, for example, the blending module 308 can determine a blending weight.

At an operation 1006, for example, the blending module 308 can produce, based on the blending weight, a blended image of the denoised image and the regularized image.

In FIG. 10B, in the method 1000, at an operation 1008, for example, the denoising module 310 can denoise the blended image to produce the image to design the product.

At an operation 1010, for example, the communications module 312 can cause the image to be sent to the computer-aided design (CAD) system 314 to design the product. For example, the output of the CAD system 314 can be used to control the machine that manufactures the product.

In FIGS. 10A and 10B, in the method 1000, for example, the operation 1002, the operation 1004, the operation 1006, the operation 1008, and the operation 1010 can be performed in iterations. For example, at the operation 1008, the denoising module 310 can denoise, in a manner in accordance with a Denoising Diffusion Implicit Model, the blended image. For example, a final iteration, of the iterations, can be a specific count (e.g., 200) of a number of the iterations. In FIG. 10B, in the method 1000, alternatively, at an operation 1012, for example, the evaluation module 316 can determine a value of a metric indicative of a quality of the image. For example, the metric can include one or more of a degree of conformity between the image and the visual pattern, a distance between a distribution associated with the image and a target distribution, or the like. For example, a final iteration, of the iterations, can be an iteration in which the value satisfies a threshold value.

In FIG. 10A, in the method 1000, additionally, at an operation 1014, for example, the diffusion module 318 can produce the first diffused image. For example, at the operation 1014, the diffusion module 318 can produce the first diffused image by adding a shared noise to a first original image.

Additionally, at an operation 1016, for example, the diffusion module 318 can produce the second diffused image. For example, at the operation 1016, the diffusion module 318 can produce the first diffused image by adding the shared noise to a second original image.

Additionally, at an operation 1018, for example, the interpolation module 320 can produce the interpolation. For example, the interpolation can include one or more of a spherical linear interpolation, a weighted average interpolation, or the like.

Additionally, at an operation 1020, for example, the denoising module 310 can produce the denoised image.

Additionally and alternatively, at an operation 1022, for example, the first encoding module 322 can encode the first original image into a first vector. For example, the first vector can be a first latent vector.

Additionally and alternatively, at an operation 1024, for example, the first encoding module 322 can encode the second original image into a second vector. For example, the second vector can be a second latent vector.

Alternatively, at the operation 1014, for example, the diffusion module 318 can produce a first diffused vector by adding the shared noise to the first vector.

Alternatively, at the operation 1016, for example, the diffusion module 318 can produce a second diffused vector by adding the shared noise to the second vector.

Alternatively, at the operation 1018, for example, the interpolation module 320 can produce an interpolation of the first diffused vector and the second diffused vector.

Alternatively, at the operation 1020, for example, the denoising module 310 can produce a denoised vector.

Additionally and alternatively, at an operation 1026, for example, the decoding module 324 can decode the denoised vector to produce a decoded denoised image.

Alternatively, at the operation 1002, for example, the regularizing module 306 can produce the regularized image of the decoded denoised image.

Additionally and alternatively, at an operation 1028, for example, the second encoding module 326 can encode the regularized image into a regularized vector.

Alternatively, at the operation 1004, for example, the blending module 308 can produce a blended vector of the denoised vector and the regularized vector.

Alternatively, at the operation 1006, for example, the denoising module 310 can denoise the blended vector to produce a modified denoised vector.

In FIG. 10B, in the method 1000, additionally and alternatively, at an operation 1030, for example, the decoding module 324 can decode the modified denoised vector to produce the image to design the product.

In FIG. 10A, in the method 1000, for example, if the visual pattern includes a rotational symmetry, then at the operation 1002, the regularizing module 306 can produce the regularized image by producing, from the denoised (or decoded denoised) image, a set of sub-images at a set of positions within the denoised image. For example, each sub-image, of the set of sub-images, can be associated with a corresponding resemblance to a pattern and a corresponding position within the set of positions.

For example, if the visual pattern includes the rotational symmetry, then at the operation 1002, the regularizing module 306 can produce the regularized image by producing an average sub-image. For example, a value of each pixel in the average sub-image can be an average of values of corresponding pixels in sub-images in the set of sub-images.

For example, if the visual pattern includes the rotational symmetry, then at the operation 1002, the regularizing module 306 can produce the regularized image by causing a copy of the average sub-image to be positioned at each position in the set of positions to produce the regularized image.

Alternatively, if the visual pattern includes a rotational symmetry, then for example, at the operation 1002, the regularizing module 306 can produce the regularized image by producing, from the denoised (or decoded denoised) image, a set of sub-images at a set of positions within the denoised image. For example, each sub-image, of the set of sub-images, can be associated with a corresponding resemblance to a pattern and a corresponding position within the set of positions.

For example, if the visual pattern includes the rotational symmetry, then at the operation 1002, the regularizing module 306 can produce the regularized image by selecting, from the set of sub-images, a specific sub-image.

For example, if the visual pattern includes the rotational symmetry, then at the operation 1002, the regularizing module 306 can produce the regularized image by causing a copy of the specific sub-image to be positioned at each position in the set of positions to produce the regularized image.

For example, at the operation 1004, the blending module 308 can determine the blending weight by determining an absolute value of a cosine similarity between the denoised image (or vector) and the regularized image (or vector).

For example, at the operation 1006, the blending module 308 can produce the blended image (or vector) by: (1) determining a first product, (2) determining a difference, (3) determining a second product, and (4) determining a sum. For example, the first product can be equal to the regularized image (or vector) multiplied by the blending weight. For example, the difference can be equal to the blending weight subtracted from one. For example, the second product can be equal to the denoised image (or vector) multiplied by the difference. For example, the sum can be equal to the first product added to the second product.

Additionally, for example, the operation 1004 can be performed in iterations and the blending module 308 can determine the blending weight by determining a third product. For example, the third product can be equal to the absolute value of the cosine similarity multiplied by a quotient. For example, the quotient can be equal to a weight divided by a decay speed factor. For example, the decay speed factor can be equal to a time variable raised to a power of a constant. For example, the time variable can be indicative of a current count of a number of the iterations. In this manner, an effect of the regularized image (or vector) on the blended image (or vector) can be reduced with each iteration.

Detailed embodiments are disclosed herein. However, one of skill in the art understands, in light of the description herein, that the disclosed embodiments are intended only as examples. Therefore, specific structural and functional details disclosed herein are not to be interpreted as limiting, but merely as a basis for the claims and as a representative basis for teaching one of skill in the art to variously employ the aspects herein in virtually any appropriately detailed structure. Furthermore, the terms and phrases used herein are not intended to be limiting but rather to provide an understandable description of possible implementations. Various embodiments are illustrated in FIGS. 1-9, 10A, and 10B, but the embodiments are not limited to the illustrated structure or application.

The flowchart and block diagrams in the figures illustrate the architecture, functionality, and operation of possible implementations of systems, methods, and computer program products according to various embodiments. In this regard, each block in flowcharts or block diagrams may represent a module, segment, or portion of code, which comprises one or more executable instructions for implementing the specified logical function(s). One of skill in the art understands, in light of the description herein, that, in some alternative implementations, the functions described in a block may occur out of the order depicted by the figures. For example, two blocks depicted in succession may, in fact, be executed substantially concurrently, or the blocks may be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suitable. A typical combination of hardware and software can be a processing system with computer-readable program code that, when loaded and executed, controls the processing system such that it carries out the methods described herein. The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product that comprises all the features enabling the implementation of the methods described herein and that, when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. As used herein, the phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples of the computer-readable storage medium would include, in a non-exhaustive list, the following: a portable computer diskette, a hard disk drive (HDD), a solid-state drive (SSD), a read-only memory (ROM), an erasable programmable read-only memory (EPROM or flash memory), a portable compact disc read-only memory (CD-ROM), a digital versatile disc (DVD), an optical storage device, a magnetic storage device, or any suitable combination of the foregoing. As used herein, a computer-readable storage medium may be any tangible medium that can contain or store a program for use by or in connection with an instruction execution system, apparatus, or device.

Generally, modules, as used herein, include routines, programs, objects, components, data structures, and so on that perform particular tasks or implement particular data types. In further aspects, a memory generally stores such modules. The memory associated with a module may be a buffer or may be cache embedded within a processor, a random-access memory (RAM), a ROM, a flash memory, or another suitable electronic storage medium. In still further aspects, a module as used herein, may be implemented as an application-specific integrated circuit (ASIC), a hardware component of a system on a chip (SoC), a programmable logic array (PLA), or another suitable hardware component (e.g., a central processing unit (CPU), a graphics processing unit (GPU), a field-programmable gate array (FPGA), or the like) that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the disclosed technologies may be written in any combination of one or more programming languages, including an object-oriented programming language such as Java™, Smalltalk, C++, or the like, and conventional procedural programming languages such as the “C” programming language or similar programming languages. The program code may execute entirely on a user's computer, partly on a user's computer, as a stand-alone software package, partly on a user's computer and partly on a remote computer, or entirely on a remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . or . . . ” as used herein refers to and encompasses any and all possible combinations of one or more of the associated listed items. For example, the phrase “at least one of A, B, or C” includes A only, B only, C only, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A system, comprising:
a processor; and
a memory storing:
a regularizing module including instructions that, when executed by the processor, cause the processor to produce a regularized image of a denoised image of an interpolation of a first diffused image and a second diffused image, the regularized image being regularized with respect to a visual pattern;
a blending module including instructions that, when executed by the processor, cause the processor to:
determine a blending weight, and
produce, based on the blending weight, a blended image of the denoised image and the regularized image;
a denoising module including instructions that, when executed by the processor, cause the processor to denoise the blended image to produce an image to design a product; and
a communications module including instructions that, when executed by the processor, cause the processor to cause the image to be sent to a computer-aided design system to design the product.

2. The system of claim 1, wherein the system is implemented using a U-net neural network.

3. The system of claim 1, wherein the system is implemented using a transformer neural network.

4. The system of claim 1, wherein the instructions to produce the regularized image, the instructions to determine the blending weight, the instructions to produce the blended image, and the instructions to denoise the blended image are performed in iterations.

5. The system of claim 4, wherein the instructions to denoise the blended image include instructions to denoise, in a manner in accordance with a Denoising Diffusion Implicit Model, the blended image.

6. The system of claim 4, wherein a final iteration, of the iterations, is a specific count of a number of the iterations.

7. The system of claim 4, wherein:
the memory further stores an evaluation module including instructions that, when executed by the processor, cause the processor to determine a value of a metric indicative of a quality of the image,
the metric comprises at least one of a degree of conformity between the image and the visual pattern or a distance between a distribution associated with the image and a target distribution, and
a final iteration, of the iterations, is an iteration in which the value satisfies a threshold value.

8. The system of claim 1, wherein:
the memory further stores:
a diffusion module including instructions that, when executed by the processor, cause the processor to:
produce the first diffused image, and
produce the second diffused image; and
an interpolation module including instructions that, when executed by the processor, cause the processor to produce the interpolation,
the denoising module further includes instructions to produce the denoised image.

9. The system of claim 8, wherein:
the instructions to produce the first diffused image include instructions to add a shared noise to a first original image, and
the instructions to produce the second diffused image include instructions to add the shared noise to a second original image.

10. The system of claim 9, wherein:
the memory further stores a first encoding module including instructions that, when executed by the processor, cause the processor to:
encode the first original image into a first vector; and
encode the second original image into a second vector,
the instructions to produce the first diffused image include instructions to produce a first diffused vector by adding the shared noise to the first vector,
the instructions to produce the second diffused image include instructions to produce a second diffused vector by adding the shared noise to the second vector,
the instructions to produce the interpolation include instructions to produce an interpolation of the first diffused vector and the second diffused vector,
the instructions to produce the denoised image include instructions to produce a denoised vector,
the memory further stores a decoding module including instructions that, when executed by the processor, cause the processor to decode the denoised vector to produce a decoded denoised image,
the instructions to produce the regularized image of the denoised image include instructions to produce the regularized image of the decoded denoised image,
the memory further stores a second encoding module including instructions that, when executed by the processor, cause the processor to encode the regularized image into a regularized vector,
the instructions to produce the blended image of the denoised image and the regularized image include instructions to produce a blended vector of the denoised vector and the regularized vector,
the instructions to denoise the blended image to produce the image to design the product include instructions to denoise the blended vector to produce a modified denoised vector, and
the decoding module further includes instructions to decode the modified denoised vector to produce the image to design the product.

11. The system of claim 10, wherein:
the first vector is a first latent vector, and
the second vector is a second latent vector.

12. The system of claim 1, wherein the visual pattern is representative of a functional constraint.

13. The system of claim 12, wherein the functional constraint comprises a constraint with respect to at least one of a rotational symmetry, a reflectional symmetry, a point symmetry, a structural strength, a shearing force, a resonant frequency, or an aerodynamic parameter.

14. The system of claim 12, wherein:
the functional constraint comprises a constraint with respect to a rotational symmetry,
the rotational symmetry comprises a pattern that repeats in a specific number of positions within an image, and
the instructions to produce the regularized image include:
instructions to produce, from the denoised image, a set of sub-images at a set of positions within the denoised image, each sub-image, of the set of sub-images, being associated with a corresponding resemblance to a pattern and a corresponding position within the set of positions,
instructions to produce an average sub-image, a value of each pixel in the average sub-image being an average of values of corresponding pixels in sub-images in the set of sub-images, and
instructions to cause a copy of the average sub-image to be positioned at each position in the set of positions to produce the regularized image.

15. The system of claim 12, wherein:
the functional constraint comprises a constraint with respect to a rotational symmetry,
the rotational symmetry comprises a pattern that repeats in a specific number of positions within an image, and
the instructions to produce the regularized image include:
instructions to produce, from the denoised image, a set of sub-images at a set of positions within the denoised image, each sub-image, of the set of sub-images, being associated with a corresponding resemblance to a pattern and a corresponding position within the set of positions,
instructions to select, from the set of sub-images, a specific sub-image, and
instructions to cause a copy of the specific sub-image to be positioned at each position in the set of positions to produce the regularized image.

16. The system of claim 1, wherein:
the instructions to determine the blending weight include instructions to determine an absolute value of a cosine similarity between the denoised image and the regularized image, and
the instructions to produce the blended image include:
instructions to determine a first product, the first product being equal to the regularized image multiplied by the blending weight,
instructions to determine a difference, the difference being equal to the blending weight subtracted from one,
instructions to determine a second product, the second product being equal to the denoised image multiplied by the difference, and
instructions to determine a sum, the sum being equal to the first product added to the second product.

17. The system of claim 16, wherein the instructions to determine the blending weight:
are performed in iterations, and
further include instructions to determine a third product, the third product being equal to the absolute value of the cosine similarity multiplied by a quotient, the quotient being equal to a weight divided by a decay speed factor, the decay speed factor being equal to a time variable raised to a power of a constant, the time variable being indicative of a current count of a number of the iterations.

18. A method, comprising:
producing, by a processor, a regularized image of a denoised image of an interpolation of a first diffused image and a second diffused image, the regularized image being regularized with respect to a visual pattern;
determining, by the processor, a blending weight;
producing, by the processor and based on the blending weight, a blended image of the denoised image and the regularized image;
denoising, by the processor, the blended image to produce an image to design a product; and
causing, by the processor, the image to be sent to a computer-aided design system to design the product.

19. The method of claim 18, wherein the interpolation comprises at least one of a spherical linear interpolation or a weighted average interpolation.

20. A non-transitory computer-readable medium for producing an image to design a product, the non-transitory computer-readable medium including instructions that, when executed by one or more processors, cause the one or more processors to:
produce a regularized image of a denoised image of an interpolation of a first diffused image and a second diffused image, the regularized image being regularized with respect to a visual pattern;
determine a blending weight;
produce, based on the blending weight, a blended image of the denoised image and the regularized image;
denoise the blended image to produce the image to design the product; and
cause the image to be sent to a computer-aided design system to design the product.
